(19) United States
(12) Patent Application Publication
(10) Pub. No.: US 2017/0162723 A1
(43) Pub. Date: Jun. 8, 2017

(54) SPOT-WELDED AND ADHESIVE-BONDED INTERCONNECTS FOR SOLAR CELLS

(71) Applicants: David Fredric Joel Kavulak, Fremont, CA (US); Gabriel Harley, Mountain View, CA (US); Lewis Abra, San Francisco, CA (US); Matthieu Moors, Braine-le-Chateau (BE); George Nadim Mseis, Berkeley, CA (US); Ludovic Pierre Edmond Hudanski, Meudon (FR)

(72) Inventors: David Fredric Joel Kavulak, Fremont, CA (US); Gabriel Harley, Mountain View, CA (US); Lewis Abra, San Francisco, CA (US); Matthieu Moors, Braine-le-Chateau (BE); George Nadim Mseis, Berkeley, CA (US); Ludovic Pierre Edmond Hudanski, Meudon (FR)

(21) Appl. No.: 14/958,739

(22) Filed: Dec. 3, 2015

(51) Int. Cl. H01L 31/02

(52) U.S. Cl. CPC H01L 31/02008

(57) ABSTRACT

Approaches for fabricating spot-welded and adhesive bonded interconnects for solar cells, and the resulting solar cells, are described. In an example, a solar cell includes a substrate having a back surface and an opposing light-receiving surface. A plurality of alternating N-type and P-type semiconductor regions is disposed in or above the back surface of the substrate. A conductive contact structure is disposed on the plurality of alternating N-type and P-type semiconductor regions. An interconnect structure is electrically connected to the conductive contact structure. The interconnect structure includes a plurality of protrusions in contact with the conductive contact structure. Each of the plurality of protrusions is spot-welded to the conductive contact structure and is surrounded by an adhesive material.

### TECHNICAL FIELD

Embodiments of the present disclosure are in the field of renewable energy and, in particular, include approaches for fabricating interconnects for solar cells, and the resulting solar cells.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques for increasing the efficiency in the manufacture of solar cells, are generally desirable. Some embodiments of the present disclosure allow for increased solar cell manufacture efficiency by providing novel processes for fabricating solar cell structures. Some embodiments of the present disclosure allow for increased solar cell efficiency by providing novel solar cell structures.

### BRIEF DESCRIPTION OF THE DRAWINGS

FIG. 1 illustrates a generalized plan view of a solar cell coupled to an overlying interconnect, in accordance with one or more embodiments of the present disclosure described herein.

FIG. 2 illustrates a plan view and corresponding cross-sectional view of a state-of-the-art soldering joint for coupling an interconnect structures to a solar cell.

FIG. 3 illustrates a plan view and corresponding cross-sectional view of a state-of-the-art spot-welded joint for coupling an interconnect structures to a solar cell.

FIG. 4 is a schematic illustrating a state-of-the art weld-bonding set-up.

FIG. 5A illustrates a cross-sectional view of a coupled interconnect structure and corresponding solar cell, in accordance with an embodiment of the present disclosure.

FIG. 5B illustrates a cross-sectional view of another coupled interconnect structure and corresponding solar cell, in accordance with another embodiment of the present disclosure.

FIGS. 6A-6E illustrate cross-sectional views of various operations in a method of unifying an interconnect structure and a solar cell, in accordance with an embodiment of the present disclosure.

FIG. 7 is a flowchart including operations in a method of fabricating a solar cell corresponding to FIGS. 6A-6E, in accordance with an embodiment of the present disclosure.

FIG. 8 is a flowchart including operations in another method of fabricating a solar cell, in accordance with another embodiment of the present disclosure.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” solar cell does not necessarily imply that this solar cell is the first solar cell in a sequence; instead the term “first” is used to differentiate this solar cell from another solar cell (e.g., a “second” solar cell).

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

Approaches for fabricating spot-welded and adhesive bonded interconnects for solar cells, and the resulting solar cells, are described herein. In the following description, numerous specific details are set forth, such as specific paste compositions and process flow operations, in order to provide a thorough understanding of embodiments of the present disclosure. It will be apparent to one skilled in the art that embodiments of the present disclosure may be practiced without these specific details. In other instances, well-known fabrication techniques, such as lithography and patterning techniques, are not described in detail in order to not unnecessarily obscure embodiments of the present disclosure. Furthermore, it is to be understood that the various embodiments shown in the figures are illustrative representations and are not necessarily drawn to scale.

Disclosed herein are solar cells. In one embodiment, a solar cell includes a substrate having a back surface and an opposing light-receiving surface. A plurality of alternating N-type and P-type semiconductor regions is disposed in or above the back surface of the substrate. A conductive contact structure is disposed on the plurality of alternating N-type and P-type semiconductor regions. An interconnect structure is electrically connected to the conductive contact structure. The interconnect structure includes a plurality of protrusions in contact with the conductive contact structure. Each of the plurality of protrusions is spot-welded to the conductive contact structure and is surrounded by an adhesive material.

Also disclosed herein are methods of fabricating solar cells. In one embodiment, a method of fabricating a solar cell involves providing a solar cell including a substrate having a back surface and an opposing light-receiving surface, a plurality of alternating N-type and P-type semiconductor regions formed in or above the back surface of the substrate, and a conductive contact structure formed on the plurality of alternating N-type and P-type semiconductor regions. The method also includes forming a plurality of regions of an adhesive material on the conductive contact structure of the solar cell. The method also includes electrically connecting an interconnect structure to the conductive contact structure of the solar cell by spot-welding a plurality of protrusions of the interconnect structure to the conductive contact structure at locations corresponding to the plurality of region of the adhesive material.

In another embodiment, a method of fabricating a solar cell involves providing a solar cell including a substrate having a back surface and an opposing light-receiving surface, a plurality of alternating N-type and P-type semiconductor regions formed in or above the back surface of the substrate, and a conductive contact structure formed on the plurality of alternating N-type and P-type semiconductor regions. The method also includes providing an interconnect structure having a plurality of protrusions. The method also includes forming a plurality of regions of an adhesive material on the plurality of protrusions of the interconnect structure. The method also includes electrically connecting the interconnect structure to the conductive contact structure of the solar cell by spot-welding the plurality of protrusions of the interconnect structure to the conductive contact structure.

One or more embodiments described herein are directed to hybrid laser-adhesive weld-bonding for back contact solar cell interconnection structures. In an embodiment, spot welding of electrical interconnects is used to reduce certain critical reliability functions of joints formed between an interconnect structure and a solar cell (e.g., primarily mechanical stability under loading and corrosion resistance). A hybrid weld-bonding approach is used based on a combined resistance spot welding with adhesive bonding to overcome the above described limitations and produce a superior joint versus joints fabricated from a single approach. Since weld-bonding as typically practiced may not be feasible for interconnecting solar cells, some embodiments of the present disclosure involve use of a preformed interconnect with a dimpled region that overcomes the limitations of weld-bonding on the backside of solar cells. Advantages may include, but are not limited to, the implementation of controlled area and heights that dictate the precise location for both welding and adhesive boding. Embodiments described herein may be compatible with laser spot welding and/or with foil-based approaches for solar cell metallization structures.

To provide context, while spot welding of interconnects is sufficient from an electrical stand point, it has the potential to greatly reduce the mechanical reliability of the interconnection region. Spot welding can also lead to micro-gap regions that may be susceptible to crevice corrosion during service of a solar module, especially if the interconnection and backside metallization is fabricated from aluminum. Hybrid adhesive-welding may overcome such performance and reliability issues but may be incompatible with thinner and more delicate silicon wafers, and with laser spot welding processing which may be used to pattern metal foil-based solar cell metallization regions.

In accordance with one or more embodiments of the present disclosure, a prefabricated interconnect is provided with a predefined dimpled region. When placed during a solar cell stringing process, only a small amount of pressure distal from the joint is needed to squeeze an associated adhesive region out from under a corresponding weld area. The weld area remains open from the top side to allow for a laser spot welding process inside the dimpled region. The limited contact area may further confine heat dissipation during welding and may improve the quality and speed of the welding process. In an embodiment, the height of the dimpled region is selected to provide a consistent adhesive bond height, thus providing for an improved manufacturing process that ensures proper joint construction.

More specific embodiments include the use of an adhesive region to provide a tackiness to the cell during the stringing process such that pick-n-place processing can be decoupled from an actual welding step. It is to be appreciated that when no adhesive is used, such processes cannot be separated since there is no way to keep the interconnect structure from moving during indexing. In some embodiments, the adhesive fills in a micro-gap region between an interconnect structure and a cell pad area that is not welded. Such fill with the adhesive material may eliminate a crevice corrosion risk that may otherwise occur if spot welding alone is used. Furthermore, in an embodiment, overall joint strength is improved by implementing processes described herein since a relatively larger adhesion region is used and since the elastic properties of the adhesive impart improved fatigue and stress reduction. It is to be appreciated that solder is currently implemented in state-of-the-art processing as a stress reducer in for interconnect design. However, such a solder approach may not be needed if a welding process is implemented, as described below.

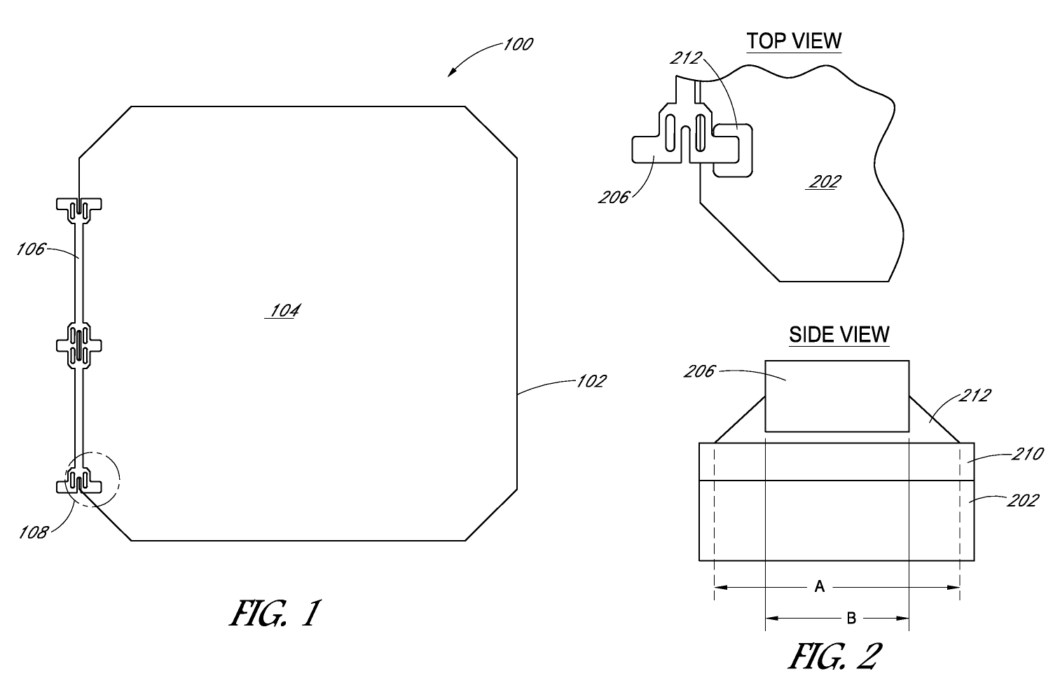

In order to provide visual context for embodiments described herein FIG. 1 illustrates a generalized plan view of a solar cell coupled to an overlying interconnect, in accordance with one or more embodiments of the present disclosure described herein.

Referring to FIG. 1, an interconnect structure 106 is coupled to a surface 104 of a substrate 102 of a solar cell 100. The interconnect structure 106 may be referred to herein as an M3 layer. In an embodiment, the surface 104 is a back surface of the solar cell 100, opposite a light-receiving surface of the solar cell (which may be a texturized light-receiving surface of the solar cell 100). Although not depicted, the interconnect structure 106 may be electrically coupled to a metallization layer (M2) coupled to alternating N-type and P-type semiconductor regions which form emitter regions for the solar cell 100. A further intervening layer (M1) may be disposed between the metallization layer (M2) and the alternating N-type and P-type semiconductor regions, examples of which are described in greater detail below. It is to be appreciated that although only one substrate 102 is depicted, the interconnect structure may be used to couple two or more substrates. In an embodiment, the substrates are single-crystalline silicon substrates. Further discussion below focuses significantly on region 108 of FIG. 1, where the interconnect structure 106 is coupled to the substrate 102 of the solar cell 100.

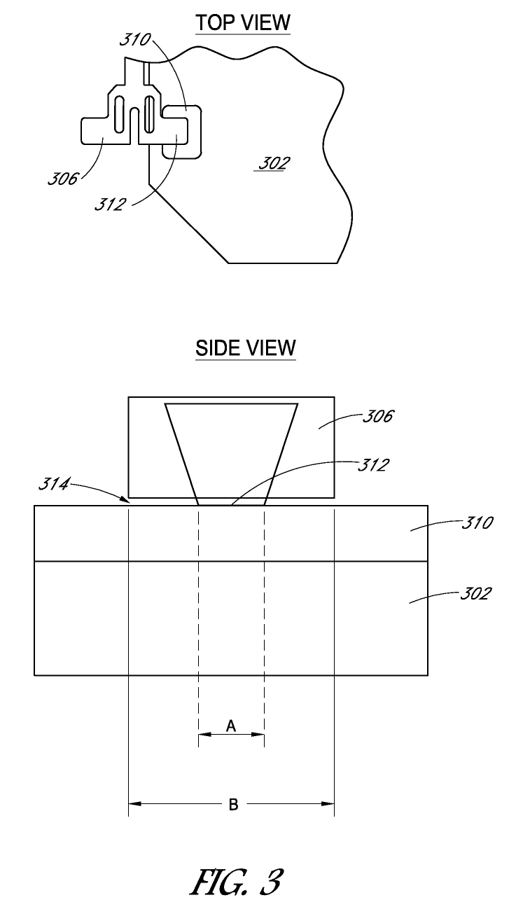

As a reference for one or more embodiments of the present disclosure, FIG. 2 illustrates a plan view and corresponding cross-sectional view of a state-of-the-art soldering joint for coupling an interconnect structures to a solar cell. Referring to FIG. 2, a portion of a substrate 202 of a solar cell 200 and a portion of an interconnect structure 206 are depicted, corresponding to one possible configuration of region 108 of FIG. 1. The interconnect structure 206 is coupled to a metal layer 210 of the solar cell 200 by a solder joint 212.

Referring again to FIG. 2, state-of-the-art processing involves stringing together of solar cells using solder 212 to join cells together via a stamped interconnect 206. The solder 212 provides both an electrical connection between the cells and significantly influences the mechanical behavior of the system. The mechanical properties of the solder bond 212 are also critical for the long term field reliability of solar modules under real world stresses such as wind loading, snow loading, thermal cycling, shipping vibrations, etc. Both the shape, large area and the softness of the solder 212 provides an improvement in the local stress. For example, bond area A is greater than the dimension B of the interconnect structure 206 to which it is coupled.

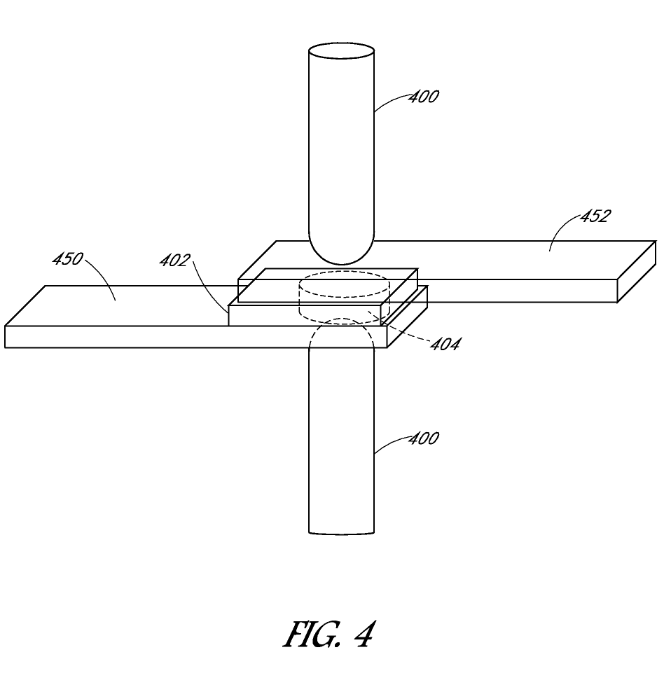

As another reference for one or more embodiments of the present disclosure, FIG. 3 illustrates a plan view and corresponding cross-sectional view of a state-of-the-art spot-welded joint for coupling an interconnect structures to a solar cell. Referring to FIG. 3, a portion of a substrate 302 of a solar cell 300 and a portion of an interconnect structure 306 are depicted, corresponding to another possible configuration of region 108 of FIG. 1. The interconnect structure 306 is coupled to a metal layer 310 of the solar cell 300 by spot weld 312.

Referring again to FIG. 3 a spot welding approach (e.g., a laser spot weld or spot welds formed from resistance or ultrasonic welding) provides the spot weld 312 having a smaller effective bond size for the same size part as the interconnect structure. The smaller bond size provides sufficient electrical conduction. However, the lower bond size (e.g., A<B) decreases the effective area to carry a load and therefore increases the local stress at the joint 312. Furthermore, spot weld 312 involves a direct metal weld which may be difficult for complete attachment as compared with a soft solder in between, further possibly leading to increased local stress. The spot welding process may leave some regions as not being bonded and, thus, has the potential to leave micro-gaps 314 in between the interconnect structure 306 and the substrate 302, as is depicted in FIG. 3. Such a crevice may have the potential to lead to corrosion under environmental conditions.

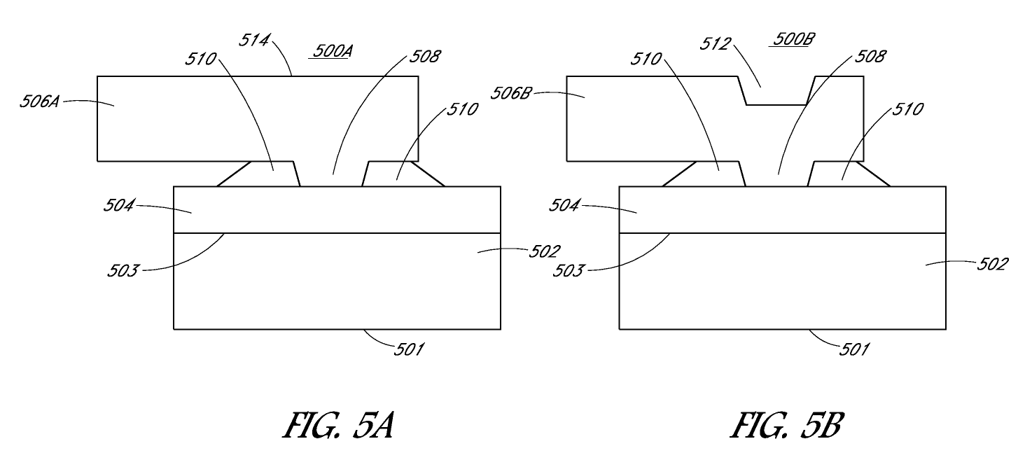

As another reference for one or more embodiments of the present disclosure, FIG. 4 is a schematic illustrating a state-of-the art weld-bonding set-up. Referring to FIG. 4, one possible approach to counteracting the above described issues of spot welding is to implement a hybrid bonding method referred to as weld-bonding. A weld-bonding approach typically involves resistance spot welding of either steel or aluminum (e.g., welding of a first metal layer 450 and a second metal layer 452). The process combines welding (using resistance welding electrodes 400) along with an adhesive bonding material 402 to form a hybrid joint at a pressure zone 404 that squeezes out adhesive material at that location, as is depicted in FIG. 4.

With reference again to FIG. 4, the weld-bonding approach can be implemented to improve mechanical reliability of the resulting joint as well as improve corrosion resistance around the resulting joint structure. The process may be performed by first applying uncured adhesive 402 to the first metal layer 450. The second metal layer 452 is placed on the first metal layer 450. Welding electrodes 400 are used to press hard on the two metal layers 450 and 452. The pressing of the electrodes 400 forces the adhesive 402 to flow out from under the area 404 where the welding is to take place (i.e., in the pressure region). Welding is then performed (e.g., resistive welding), and the resulting joint is cured in an oven or by another suitable approach. However, the welding described in association with FIG. 4 may not be suitable for foil-based metallization structures since a significant pressure may not be suitable for such structures without running the risk of damage or cracking.

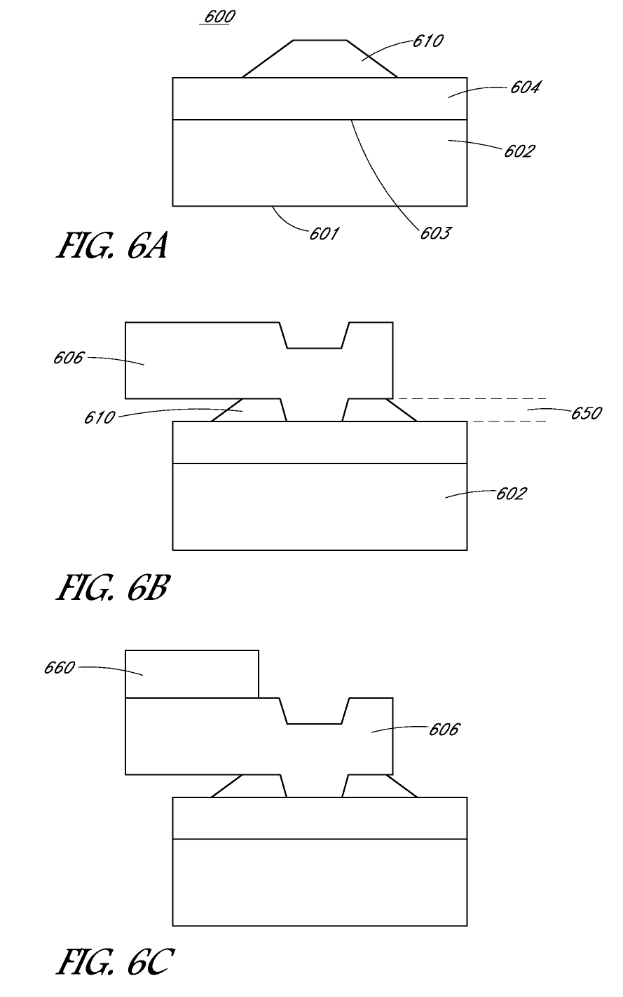

As exemplary implementations of one or more embodiments of the present disclosure, FIGS. 5A and 5B illustrate cross-sectional view of a coupled interconnect structure and corresponding solar cell, in accordance with an embodiment of the present disclosure. Referring to FIGS. 5A and 5B, a portion of a substrate 502 of a solar cell 500A or 500B and a portion of an interconnect structure 506A or 506B, respectively, are depicted, corresponding to two possible configurations of region 108 of FIG. 1.

Referring to both FIGS. 5A and 5B, a solar cell 500A or 500B includes a substrate 502 having a back surface 503 and an opposing light-receiving surface 501. A plurality of alternating N-type and P-type semiconductor regions (shown generally as part of feature 504) is disposed in or above the back surface 503 of the substrate 502. A conductive contact structure (also shown generally as part of feature 504) is disposed on the plurality of alternating N-type and P-type semiconductor regions. An interconnect structure 506A or 506B is electrically connected to the conductive contact structure 504. The interconnect structure 506A or 506B includes a plurality of protrusions (one protrusion shown as 508) in contact with the conductive contact structure 504. Each of the plurality of protrusions 502 is spot-welded to the conductive contact structure 504 and is surrounded by an adhesive material 510 (it is to be appreciated that adhesive material 510 surrounds each of the plurality of protrusions 502 into and out of the page of the view shown in FIGS. 5A and 5B).

Referring to FIG. 5B only, in an embodiment, each of the plurality of protrusions 508 has a corresponding indentation (or dimpled region) 512 in the interconnect structure 506B. Referring only to FIG. 5A, in an embodiment, a surface 514 of the interconnect structure 506A opposite the plurality of protrusions 508 is substantially flat.

Referring again to both FIGS. 5A and 5B, in an embodiment, the adhesive material 510 is a material such as, but not limited to, an epoxy, an aliphatic urethane, an acrylic, a modified polyolefin, a polyimide, or a silicone. In an embodiment, the adhesive material 510 is in contact with the interconnect structure 506A or 506B and with the conductive contact structure 504. In one such embodiment, the adhesive material 510 has a thickness approximately in the range of 0.5-2 microns.

In an embodiment, the conductive contact structure 504 includes a metal foil, and each of the plurality of protrusions 508 of the interconnect structure 506A or 506B is spot-welded to the metal foil. In an embodiment, the conductive contact structure 504 further includes a metal seed layer disposed between the plurality of alternating N-type and P-type semiconductor regions and the metal foil. In an embodiment, the substrate 502 is a monocrystalline silicon substrate, and the plurality of alternating N-type and P-type semiconductor regions is a plurality of N-type and P-type diffusion regions formed in the silicon substrate 502. In another embodiment, however, the plurality of alternating N-type and P-type semiconductor regions is a plurality of N-type and P-type polycrystalline silicon regions formed above the back surface of the substrate 502.

Referring again to both FIGS. 5A and 5B, in an embodiment, structures 500A and 500B eliminate micro-gap regions and reduce the likelihood of localized corrosion issues at interconnect structure and solar cell interfaces. The adhesive composition can be designed for mechanical stability, long term reliability, corrosion protection, curing method, and stability during laser welding. The adhesive material also provides a tackiness to the cell surface. This allows for placement of the interconnect structure and then index the interconnect structure and solar cell another station for welding without issues otherwise associated with movement. In an exemplary embodiment, cell stresses calculated when subjected to an approximately 950N force, a bending load can be approximated for the above method of interconnection. In one such study, cells that are welded have an approximately 37% increase in stress, whereas cells that are soldered have only an approximately 14% increase. Accordingly, using an adhesive to mitigate movement during interconnection can render a welding process more feasible.

Referring to FIG. 5B only, in an embodiment, a pre-dimpled interconnect piece is used to provide the local pressure and to set the effective bond height of the adhesive layer. The system also provides a specific region that is accessible for laser spot welding and may improve welding since it can increase the temperature of the heat affected zone (HAZ). The dimpled region may take on many shapes and sizes and can be optimized to improve welding and overall joint performance. It is to be appreciated that the arrangement shown in FIG. 5A provides a flat surface, possibly providing increased tolerance for a laser spot welding process.

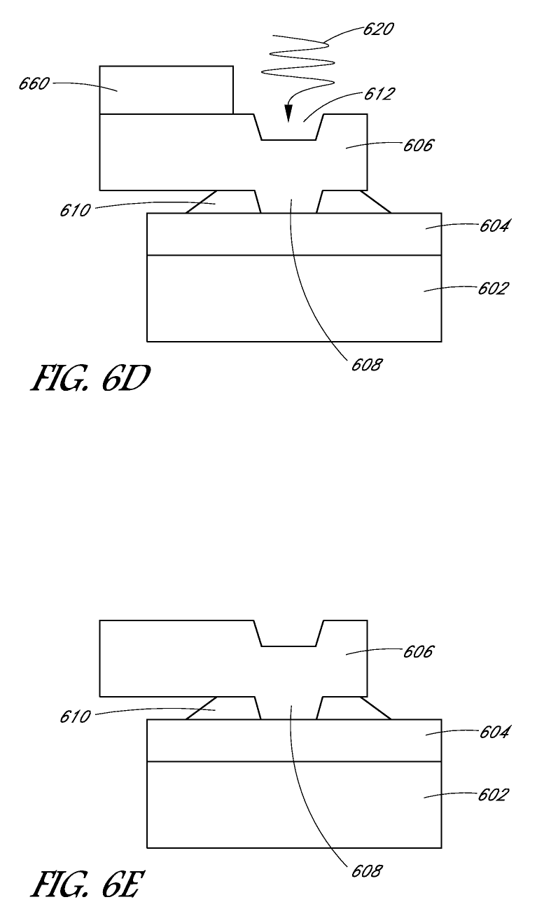

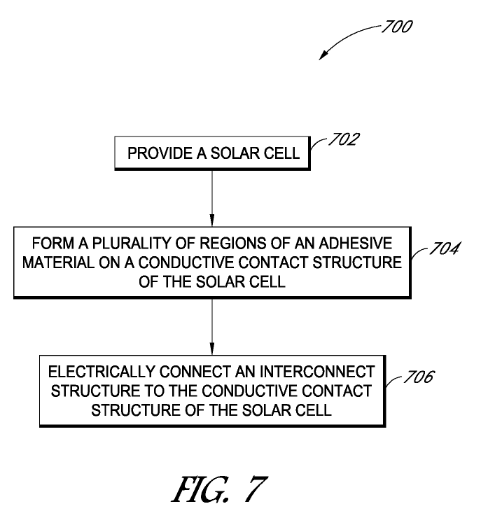

It is to be appreciated that structures described in association with FIGS. 5A and 5B may be fabricated by one of several approaches. As an exemplary processing scheme, FIGS. 6A-6E illustrate cross-sectional views of various operations in a method of unifying an interconnect structure and a solar cell, in accordance with an embodiment of the present disclosure. FIG. 7 is a flowchart 700 including operations corresponding to FIGS. 6A-6E, in accordance with an embodiment of the present disclosure. Generally, an exemplary process may involve one or more of dispensing an adhesive, placement of an interconnect, either dimpling during a stringing process or use of a pre-dimpled or pre-protrusion formed interconnect, use of a hold down fixture to apply light pressure on the interconnect structure and squeeze out of the adhesive from a weld location, laser welding, and curing the adhesive either in a stringer using oven, through IR, etc., or curing during a subsequent lamination process.

Referring to operation 702 of flowchart 700 and corresponding FIG. 6A, a method of fabricating a solar cell involves providing a solar cell 600 including a substrate 602 having a back surface 603 and an opposing light-receiving surface 601, a plurality of alternating N-type and P-type semiconductor regions (shown generally as feature 604) formed in or above the back surface 603 of the substrate 602, and a conductive contact structure (also shown generally feature 604) formed on the plurality of alternating N-type and P-type semiconductor regions.

Referring to operation 704 of flowchart 700 and again to corresponding FIG. 6A, the method also includes forming a plurality of regions of an adhesive material 610 on the conductive contact structure 604 of the solar cell 600. Referring to 6B, an interconnect structure 606 is placed over the substrate 602 and into the adhesive material 610. In an embodiment, the region of adhesive material 610 has a thickness approximately in the range of 30-130 microns as originally formed (e.g., in FIG. 6A). Upon coupling the interconnect structure 606 with the substrate 602, the thickness of the adhesive material 610 is reduced reducing to a thickness 650 approximately in the range of 0.5-2 microns.

Referring to FIG. 6C, a pressure applicator 660 is used to hold the interconnect structure 606 in place. Referring to operation 706 of flowchart 700 and now to corresponding FIG. 6D, the method also includes electrically connecting the interconnect structure 606 to the conductive contact structure 604 of the substrate 602 of the solar cell by spot-welding 620 a plurality of protrusions 608 of the interconnect structure 606 to the conductive contact structure 604 at locations corresponding to the plurality of regions of the adhesive material 610. Referring to FIG. 6E, the pressure applicator 660 is removed and the interconnect structure 606 remains spot-welded to the conductive contact structure 604 through protrusions 608 at locations corresponding to the plurality of regions of the adhesive material 610.

In an embodiment, spot-welding 620 the plurality of protrusions 608 of the interconnect structure 606 to the conductive contact structure 604 involves laser-welding the plurality of protrusions 608 of the interconnect structure 606 to the conductive contact structure 604. In another embodiment, spot-welding 620 the plurality of protrusions 608 of the interconnect structure 606 to the conductive contact structure 604 involves resistive-welding the plurality of protrusions 608 of the interconnect structure 606 to the conductive contact structure 604. In an embodiment, the conductive contact structure 604 includes a metal foil, and electrically connecting the interconnect structure 606 to the conductive contact structure 604 involves electrically connecting each of the plurality of protrusions 608 of the interconnect structure 606 to the metal foil.

Referring again to FIG. 6D, spot-welding 620 the plurality of protrusions 608 of the interconnect structure 606 to the conductive contact structure 604 involves spot-welding 620 a plurality of protrusions each having a corresponding indentation 612 in the interconnect structure 606 (as was also described in association with FIG. 5B). However, in another embodiment (as was described in association with FIG. 5A), each of the plurality of protrusions 608 does not have a corresponding indentation in the interconnect structure 608.

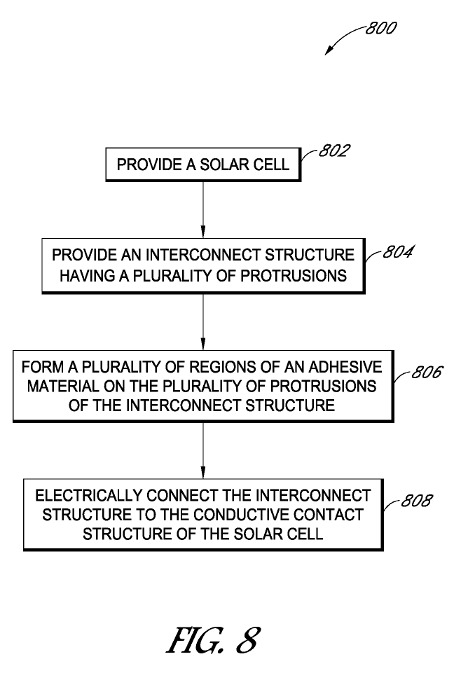

As another exemplary processing scheme, FIG. 8 is a flowchart 800 of various operations in a method of fabricating a solar cell, in accordance with an embodiment of the present disclosure.

Referring to operation 802 of flowchart 800, a method of fabricating a solar cell involves providing a solar cell including a substrate having a back surface and an opposing light-receiving surface, a plurality of alternating N-type and P-type semiconductor regions formed in or above the back surface of the substrate, and a conductive contact structure formed on the plurality of alternating N-type and P-type semiconductor regions.

Referring to operation 804 of flowchart 800, the method also includes providing an interconnect structure having a plurality of protrusions. The method also includes forming a plurality of regions of an adhesive material on the plurality of protrusions of the interconnect structure, as depicted in operation 806 of flowchart 800.

In an embodiment, forming the plurality of regions of the adhesive material involves forming a plurality of regions of a material such as, but not limited to, an epoxy, an aliphatic urethane, an acrylic, a modified polyolefin, a polyimide, or a silicone. In an embodiment, forming the plurality of regions of the adhesive material involves forming a plurality of regions of the adhesive material having a thickness approximately in the range of 30-130 microns.

Referring to operation 806 of flowchart 800, the method also includes electrically connecting the interconnect structure to the conductive contact structure of the solar cell by spot-welding the plurality of protrusions of the interconnect structure to the conductive contact structure.

In an embodiment, spot-welding the plurality of protrusions of the interconnect structure to the conductive contact structure involves laser-welding the plurality of protrusions of the interconnect structure to the conductive contact structure. In an embodiment, spot-welding the plurality of protrusions of the interconnect structure to the conductive contact structure involves resistive-welding the plurality of protrusions of the interconnect structure to the conductive contact structure. In an embodiment, the conductive contact structure includes a metal foil, and electrically connecting the interconnect structure to the conductive contact structure involves electrically connecting each of the plurality of protrusions of the interconnect structure to the metal foil.

In an embodiment, spot-welding the plurality of protrusions of the interconnect structure to the conductive contact structure involves spot-welding a plurality of protrusions each having a corresponding indentation in the interconnect structure (as described in association with FIG. 5B). In an embodiment, spot-welding the plurality of protrusions of the interconnect structure to the conductive contact structure involves spot-welding a plurality of protrusions each without a corresponding indentation in the interconnect structure (as described in association with FIG. 5A). In an embodiment, electrically connecting the interconnect structure to the conductive contact structure involves reducing the thickness of the plurality of regions of the adhesive material to a thickness approximately in the range of 0.5-2 microns.

In an embodiment, as applicable to embodiments described above, alternating N-type and P-type semiconductor regions described herein are formed from polycrystalline silicon. In one such embodiment, the N-type polycrystalline silicon emitter regions are doped with an N-type impurity, such as phosphorus. The P-type polycrystalline silicon emitter regions are doped with a P-type impurity, such as boron. The alternating N-type and P-type semiconductor regions may have trenches formed there between, the trenches extending partially into the substrate. Additionally, although not depicted, in one embodiment, a bottom anti-reflective coating (BARC) material or other protective layer (such as a layer amorphous silicon) may be formed on the alternating N-type and P-type semiconductor regions. The alternating N-type and P-type semiconductor regions may be formed on a thin dielectric tunneling layer formed on the back surface of the substrate.

In an embodiment, as applicable to embodiments described above, a light receiving surface of a solar cell described herein may be a texturized light-receiving surface. In one embodiment, a hydroxide-based wet etchant is employed to texturize the light receiving surface of the substrate. In an embodiment, a texturized surface may be one which has a regular or an irregular shaped surface for scattering incoming light, decreasing the amount of light reflected off of the light receiving surface of the solar cell. Additional embodiments can include formation of a passivation and/or anti-reflective coating (ARC) layers on the light-receiving surface.

In an embodiment, as applicable to embodiments described above, an M1 layer, if included, is a plurality of metal seed material regions. In a particular such embodiment, the metal seed material regions are aluminum regions each having a thickness approximately in the range of 0.3 to 20 microns and composed of aluminum in an amount greater than approximately 97% and silicon in an amount approximately in the range of 0-2%.

In an embodiment, as applicable to embodiments described above, an M2 layer as described herein is a conductive layer formed through electroplating or electroless plating. In another embodiment, an M2 layer as described herein is a metal foil layer. In one such embodiment, the metal foil is an aluminum (Al) foil having a thickness approximately in the range of 5-100 microns and, preferably, a thickness approximately in the range of 30-100 microns. In one embodiment, the Al foil is an aluminum alloy foil including aluminum and second element such as, but not limited to, copper, manganese, silicon, magnesium, zinc, tin, lithium, or combinations thereof. In one embodiment, the Al foil is a temper grade foil such as, but not limited to, F-grade (as fabricated), O-grade (full soft), H-grade (strain hardened) or T-grade (heat treated). In another embodiment, a copper foil, or a copper layer supported on a carrier, is used the “metal foil.” In some embodiments, a protective layer such as a zincate layer is included on one or both sides of the metal foil.

Although certain materials are described specifically with reference to above described embodiments, some materials may be readily substituted with others with other such embodiments remaining within the spirit and scope of embodiments of the present disclosure. For example, in an embodiment, a different material substrate, such as a group III-V material substrate, can be used instead of a silicon substrate. Additionally, although reference is made significantly to back contact solar cell arrangements, it is to be appreciated that approaches described herein may have application to front contact solar cells as well. In other embodiments, the above described approaches can be applicable to manufacturing of other than solar cells. For example, manufacturing of light emitting diode (LEDs) may benefit from approaches described herein.

Thus, approaches for fabricating spot-welded and adhesive bonded interconnects for solar cells, and the resulting solar cells, have been disclosed.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

1. A solar cell, comprising:
a substrate having a back surface and an opposing light-receiving surface;
a plurality of alternating N-type and P-type semiconductor regions disposed in or above the back surface of the substrate;
a conductive contact structure disposed on the plurality of alternating N-type and P-type semiconductor regions; and
an interconnect structure electrically connected to the conductive contact structure, the interconnect structure comprising a plurality of protrusions in contact with the conductive contact structure, the plurality of protrusions a plurality of raised portions of the interconnect structure, wherein each of the plurality of protrusions is spot-welded to the conductive contact structure and is surrounded by an adhesive material.

2. The solar cell of claim 1, wherein the conductive contact structure comprises a metal foil, and wherein each of the plurality of protrusions of the interconnect structure is spot-welded to the metal foil.

3. The solar cell of claim 1, wherein the each of the plurality of protrusions has a corresponding indentation in the interconnect structure.

4. The solar cell of claim 1, wherein a surface of the interconnect structure opposite the plurality of protrusions is substantially flat.

5. The solar cell of claim 1, wherein the adhesive material is a material selected from the group consisting of an epoxy, an aliphatic urethane, an acrylic, a modified polyolefin, a polyimide, and a silicone.

6. The solar cell of claim 1, wherein the adhesive material is in contact with the interconnect structure and with the conductive contact structure, and wherein the adhesive material has a thickness approximately in the range of 0.5-2 microns.

7. The solar cell of claim 2, wherein the conductive contact structure further comprises a metal seed layer disposed between the plurality of alternating N-type and P-type semiconductor regions and the metal foil.

8. The solar cell of claim 1, wherein the substrate is a monocrystalline silicon substrate, and wherein the plurality of alternating N-type and P-type semiconductor regions is a plurality of N-type and P-type diffusion regions formed in the silicon substrate.

9. The solar cell of claim 1, wherein the plurality of alternating N-type and P-type semiconductor regions is a plurality of N-type and P-type polycrystalline silicon regions formed above the back surface of the substrate.

10.-25. (canceled)

26. A solar cell, comprising:
a substrate having a back surface and an opposing light-receiving surface;
a plurality of alternating N-type and P-type semiconductor regions disposed in or above the back surface of the substrate;
a conductive contact structure disposed on the plurality of alternating N-type and P-type semiconductor regions, wherein the conductive contact structure comprises an aluminum foil having a thickness approximately in the range of 5-100 microns, and having a zincate layer on one or both sides of the aluminum foil; and
an interconnect structure electrically connected to the conductive contact structure, the interconnect structure comprising a plurality of protrusions in contact with the conductive contact structure, wherein each of the plurality of protrusions is spot-welded to the conductive contact structure and is surrounded by an adhesive material.

27. The solar cell of claim 26, wherein each of the plurality of protrusions of the interconnect structure is spot-welded to the aluminum foil.

28. The solar cell of claim 26, wherein the each of the plurality of protrusions has a corresponding indentation in the interconnect structure.

29. The solar cell of claim 26, wherein a surface of the interconnect structure opposite the plurality of protrusions is substantially flat.

30. The solar cell of claim 26, wherein the adhesive material is a material selected from the group consisting of an epoxy, an aliphatic urethane, an acrylic, a modified polyolefin, a polyimide, and a silicone.

31. The solar cell of claim 26, wherein the adhesive material is in contact with the interconnect structure and with the conductive contact structure, and wherein the adhesive material has a thickness approximately in the range of 0.5-2 microns.

32. The solar cell of claim 27, wherein the conductive contact structure further comprises a metal seed layer disposed between the plurality of alternating N-type and P-type semiconductor regions and the aluminum foil.

33. The solar cell of claim 26, wherein the substrate is a monocrystalline silicon substrate, and wherein the plurality of alternating N-type and P-type semiconductor regions is a plurality of N-type and P-type diffusion regions formed in the silicon substrate.

34. The solar cell of claim 26, wherein the plurality of alternating N-type and P-type semiconductor regions is a plurality of N-type and P-type polycrystalline silicon regions formed above the back surface of the substrate.

35. The solar cell of claim 26, wherein the zincate layer is on both sides of the aluminum foil.

36. The solar cell of claim 26, wherein the zincate layer is on only one side of the aluminum foil.
